(19) United States
(12) Patent Application Publication
(10) Pub. No.: US 2017/0070243 A1
(43) Pub. Date: Mar. 9, 2017

(54) EARLY TERMINATION METHOD WITH RE-ENCODING SCHEME FOR DECODING OF ERROR CORRECTION CODE

(71) Applicant: Storart Technology Co.,Ltd., Hsinchu (TW)

(72) Inventor: Jui Hui HUNG, Hsinchu (TW)

(73) Assignee: Storart Technology Co.,Ltd., Hsinchu (TW)

(21) Appl. No.: 14/847,207

(22) Filed: Sep. 8, 2015

(51) Int. Cl. H03M 13/45; H03M 13/37

(52) U.S. Cl. CPC H03M 13/458; H03M 13/3753

(57) ABSTRACT

An early termination method with a re-encoding scheme for decoding of error correction codes is disclosed. The method includes the steps of: A. receiving soft values; B. processing hard decision on the soft value to determine a codeword; C. separating the codeword into a data part and a first parity part; D. re-encoding the data part to get a second parity part; E. checking if the first parity part and the second parity part are equivalent; and F. if a result of step E is yes, stopping decoding the codeword; if the result of step E is no, processing a decoding algorithm on the codeword. By this method, the received codeword still can be correctly decoded if there are many errors in the parity region and its decoding performance can be improved.

### FIELD OF THE INVENTION

The present invention relates to a method for decoding of error correction codes. More particularly, the present invention relates to an early termination method with re-encoding scheme for decoding of error correction codes.

### BACKGROUND OF THE INVENTION

ECC (Error Correction Code) can check and correct messages with errors by adding some redundant information. The errors may be introduced during transmission from a source to a receiver or the defects of the storage device. For storage devices, ECC has been widely adopted to increase the reliability of data access and hence reduces manufacturing costs. As the increasing of the bit density and multiple-layered manufacturing processes of flash devices, the ECC plays a more and more important role. However, ECC encoders/decoders need large area cost for high decoding performance requirement. One of major area costs comes from syndrome test, which needs a lot of interconnection and XOR gates for checking correctness of codewords. Not only the total cost of a device applied the ECC is increased, but time needs to complete the decoding processes becomes longer.

In order to settle the problems above, many prior arts have provided solutions from different ways. Most of them have steps for early termination of iterative calculation. For example, U.S. Pat. No. 7,765,453 provides an early termination method for iterative forward error correction decoders and a controller using the method. The method has steps of: receiving an encoded frame of data that the encoded frame of data includes a quantity of code blocks where each code block has a corresponding code block size; determining a first maximum number of iterations for each of the code blocks of the encoded frame of data iteratively performing a decoding operation on a first code block until the occurrence of one of (a) the first maximum number of iterations has been reached and (b) the first code block has converged; and determining a second maximum number of iterations for the remaining code blocks of the encoded frame of data based on the number of actual iterations used to decode the first code block. '453 fully utilizes capacity of a chosen decoder and saves the number of iterative calculations. However, hardware (controller) to implement the method is another area cost to the decoder. Meanwhile, the architecture of the decoder can not be down-sized.

Another early termination method is disclosed in the U.S. Pat. No. 7,765,453. The method comprises steps of: receiving a test codeword based on a codeword received over a communications channel; performing, for each row of a parity check matrix, a Low Density Parity Check (LDPC) processing operation on the test codeword; once the processing operations have been performed for all the rows, repeating the processing operations; monitoring progress of the processing operations; selectively generating a termination signal in response to the test codeword being a valid codeword according to the parity check matrix; and terminating the processing operations in response to generation of the termination signal. '453 is only for LDPC. Help for reducing area cost is limited.

Therefore, an innovative early termination method is desired. Especially the method can have low hardware complexity and reduce area cost.

### SUMMARY OF THE INVENTION

In order to reduce hardware complexity, improve performance and throughput in decoding processes, an early termination method with a re-encoding scheme for decoding of error correction codes is provided in the present invention. The method includes the steps of: A. receiving soft values; B. processing hard decision on the soft value to determine a codeword; C. separating the codeword into a data part and a first parity part; D. re-encoding the data part to get a second parity part; E. checking if the first parity part and the second parity part are equivalent; and F. if a result of step E is yes, stopping decoding the codeword; if the result of step E is no, processing a decoding algorithm on the codeword.

According to the present invention, another early termination method with a re-encoding scheme for decoding of error correction codes also provided. The method includes the steps of: A. receiving first soft values; B. processing hard decision on the first soft values to determine a first codeword and processing a decoding algorithm on the first soft values to get second soft values; C. separating the first codeword into a data part and a first parity part; D. re-encoding the data part to get a second parity part; E. processing hard decision on the second soft values to determine a second codeword and a third parity part of the second codeword; F. checking if the second parity part and the third parity part are equivalent; and G. if a result of step F is yes, stopping iterative decoding; if the result of step F is no, processing the decoding algorithm on the second codeword.

Preferably, the method further includes the steps of, after step G: G1. after the decoding algorithm is processed, checking if a number of iterative calculation reaches a preset maximum number; and G2. if a result of step H1 is yes, stopping iterative calculation of the decoding algorithm; if the result of step H1 is no, returning the processed codeword as the first soft values to repeat the procedure from step A.

According to the present invention, still another early termination method with a re-encoding scheme for decoding of error correction codes also provided. The method includes the steps of: A. receiving soft values; B. processing hard decision on the soft values to determine a first codeword; C. separating the first codeword into a first data part and a first parity part; D. re-encoding the first data part to get a second codeword; E. separating the second codeword into a second data part and a second parity part; F. calculating a number of mismatched bits between the first parity part and the second parity part; G. checking if the number is greater than or equal to a preset value; and H. if a result of step G is yes, processing a decoding algorithm on the first codeword; if the result of step G is no, processing the decoding algorithm on the second codeword.

Preferably, the method further includes the steps of, after step H: H1. checking if a number of iterative calculation reaches a preset maximum number or a present termination condition of the decoding algorithm is met; and H2. if a result of step G1 is yes, stopping iterative calculation of the decoding algorithm; if the result of step G1 is no, returning the processed codeword as the soft values to repeat the procedure from step A.

With the methods provided by the present invention, received codeword correctness is checked without syndrome test to reduce decoder area cost. Meanwhile, encoder for early termination can be re-used. Decoding performance can be improved by replacing erroneous parity part based on re-encoded codeword.

### BRIEF DESCRIPTION OF THE DRAWINGS

FIG. 1 is a flow chart of an early termination method with a re-encoding scheme for decoding of error correction codes according to the present invention.

FIG. 2 is a flow chart of another early termination method with a re-encoding scheme for decoding of error correction codes according to the present invention.

FIG. 3 is a flow chart of still another early termination method with a re-encoding scheme for decoding of error correction codes according to the present invention.

### DETAILED DESCRIPTION OF THE PREFERRED EMBODIMENTS

The present invention will now be described more specifically with reference to the following embodiments.

An aspect of the present invention is to provide an early termination method by adopting re-encoding scheme to check the correctness of received codewords. It means the encoder and decoder can have some identical logics so that design cost may be reduced. Particularly, compared to conventional methods, the method provided here does not need additional hardware for syndrome test. A large area cost for the syndrome test can be saved. It should be emphasized that the present invention can be applied to codewords transmitted through a noisy wired or wireless communication channel. It can also be used to check data stored in a storage device, e.g. a Solid State Drive (SSD), where some bits might be defective. Messages received can be returned to the original condition and correct information can be available.

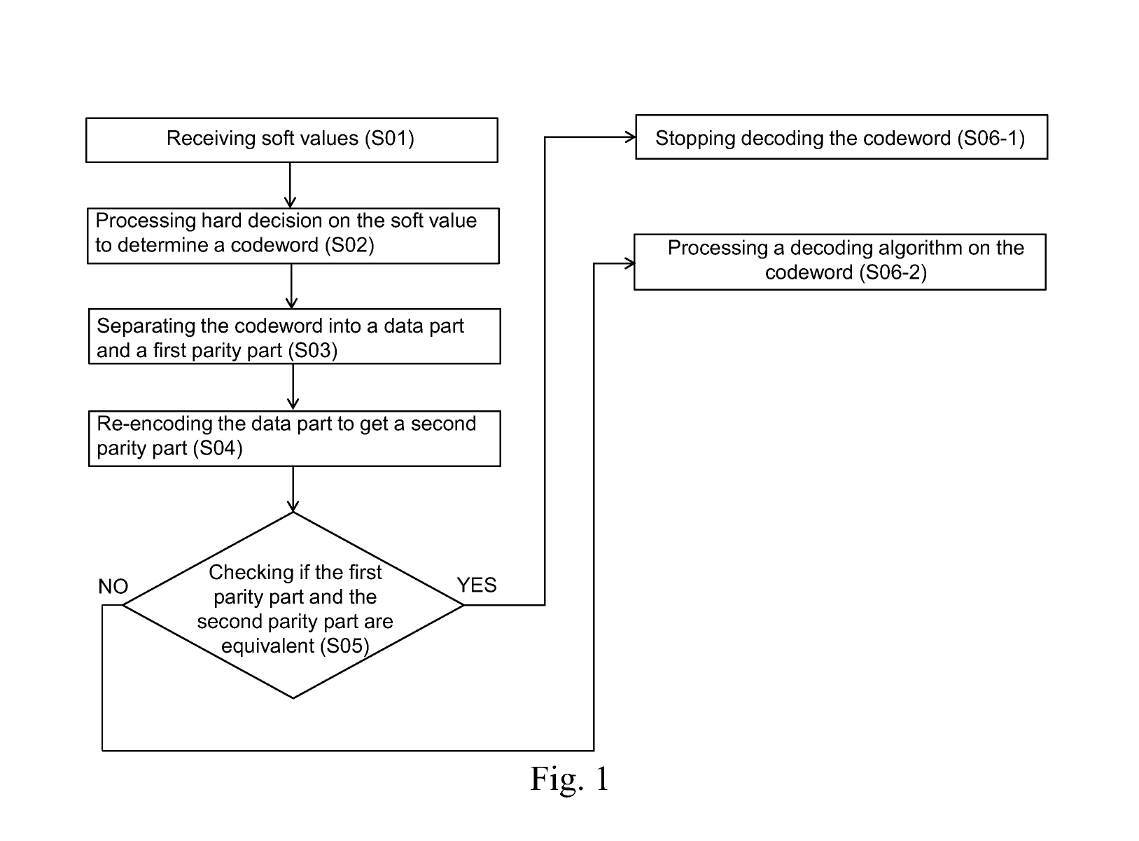

Please refer to FIG. 1. An embodiment according the present invention is illustrated. FIG. 1 is a flow chart of an early termination method with a re-encoding scheme for decoding of error correction codes according to the present invention. The first step of the method is to receive soft values from a channel or a storage device (S01). The soft values mean that the incoming data may include characteristics of the channel or storage device in order to indicate reliability, not only 0 or 1 a receiver takes. Then, a hard decision is processed on the soft value to determine a codeword (S02). The codeword is separated into two parts, a data part and a first parity part (S03). Now, the codeword may have correct message in the data part. It may have error bits in the data part and/or the first parity part. Next, re-encode the data part to get a second parity part (S04). Now, we have the first parity part and the second parity part. Check if the first parity part and the second parity part are equivalent (S05). If a result of step S05 is yes, stop decoding the codeword (S06-1); if the result of step S05 is no, processing a decoding algorithm on the codeword (S06-2). In the final step, the “yes” condition means the data part has the correct message and an early termination strategy is fulfilled. The “no” condition refers to errors exist. Further decoding processes are required.

In the embodiment above, it is obvious that if a message is correctly transmitted, the codeword doesn't need syndrome text and can be filtered out by using the same encoding circuit it was processed before being transmitted. For other conditions, codewords need to be further decoded. It can save time for decoding and area cost for hardware. However, perfect transmitting is scarce. The present invention discloses another embodiment for more detailed operations in early termination.

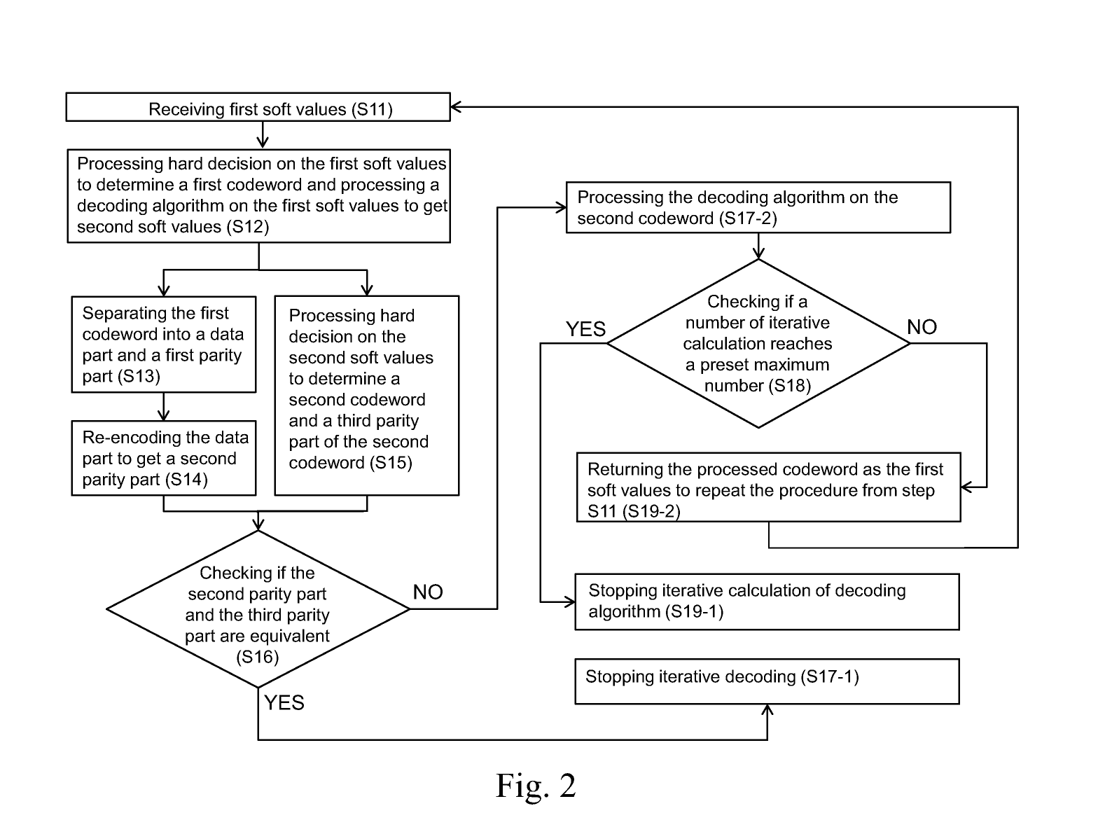

Please refer to FIG. 2. FIG. 2 is a flow chart of another embodiment of an early termination method with a re-encoding scheme for decoding of error correction codes according to the present invention. The first step is to receive first soft values (S11). Then, process hard decision on the first soft values to determine a first codeword and process a decoding algorithm on the first soft values to get second soft values (S12). It means the first soft values are treated by different processes to get different statuses. For the first codeword, separate it into a data part and a first parity part (S13). Then, re-encode the data part to get a second parity part (S14). For the second soft values, process hard decision on them to determine a second codeword and a third parity part of the second codeword (S15). It should be noticed that there must be some error found and bits flipped in the second codeword after the decoding algorithm was processed. The decoding algorithm doesn't have to be carried on completely. It is just to find out some errors if there are. Now, check if the second parity part and the third parity part are equivalent (S16). If a result of step S16 is yes, stop iterative decoding (S17-1); if the result of step F is no, processing the decoding algorithm on the second codeword (S17-2). After the decoding algorithm is processed, check if a number of iterative calculation reaches a preset maximum number (S18). The preset maximum number can be any number in any decoding algorithm. In general, the larger the number is, the longer the decoding procedure takes. Finally, if a result of step S18 is yes, stop iterative calculation of the decoding algorithm (S19-1); if the result of step S18 is no, returning the processed codeword as the first soft values to repeat the procedure from step S11 (S19-2). The “yes” condition says when the maximum number of calculation reaches, changes have been convergent and the data part is almost correct. The “no” condition shows there are still hidden errors in the codeword. The processed codeword needs to be re-treated again as new first soft values. It is obvious that errors will be less compared to the first codeword from the hard decision.

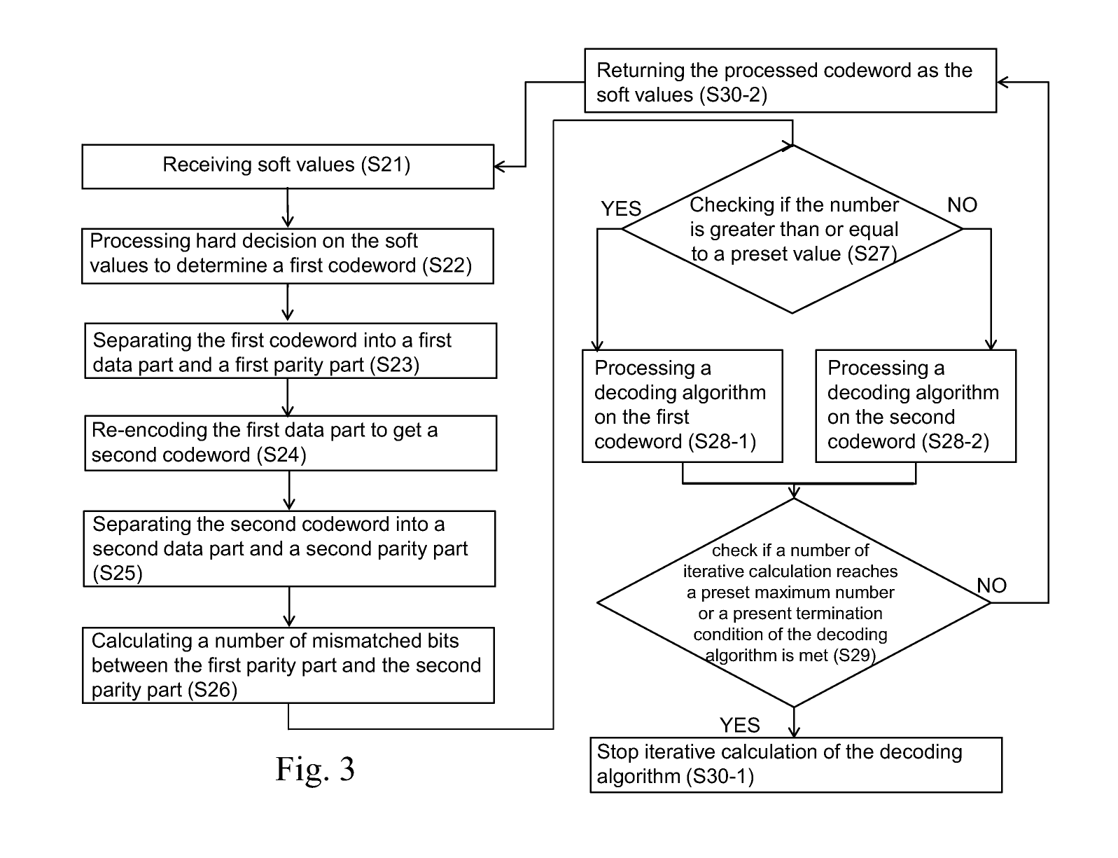

According to the present invention, the re-encoding scheme can also be used to improve decoding performance or throughput. Another proposed method compares the parity parts of received and re-encoded codewords, and checks total number of the mismatched bits in parity regions. Please see FIG. 3. FIG. 3 is a flow chart of still another embodiment of an early termination method with a re-encoding scheme for decoding of error correction codes according to the present invention. The first step is to receive soft values (S21). Then, process hard decision on the soft values to determine a first codeword (S22). Separate the first codeword into a first data part and a first parity part (S23). Take the first data part and re-encode it to get a second codeword (S24). Then, separate the second codeword into a second data part and a second parity part (S25). Calculating a number of mismatched bits between the first parity part and the second parity part (S26). Next, check if the number is greater than or equal to a preset value (S27). The preset value, N, may be any number according to designers. In general, the larger the number is, the longer the decoding procedure takes. If a result of step S27 is yes, process a decoding algorithm on the first codeword (S28-1); if the result of step S27 is no, process the decoding algorithm on the second codeword (S28-2). The goal of step S28-1 and S28-2 is to pick up a codeword with fewer errors to be further decoded. Time for decoding can be reduced. Then, check if a number of iterative calculation reaches a preset maximum number or a present termination condition of the decoding algorithm is met (S29). Use of the preset maximum number is to achieve the same target as described in the previous embodiment. The present termination condition of the decoding algorithm may be different from algorithm to algorithm. It is used to make sure decoding result has been convergent and shorten decoding time. For example, it can be a request to run step S03 to step S06-1 or S06-2 and two parity parts must be equivalent. Last, if a result of step S29 is yes, stop iterative calculation of the decoding algorithm (S30-1); if the result of step S29 is no, return the processed codeword as the soft values to repeat the procedure from step S21 (S30-2). Similarly, the “no” condition shows there are still hidden errors in the codeword. The processed codeword needs to be re-treated again as new soft values.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. An early termination method with a re-encoding scheme for decoding of error correction codes, comprising the steps of:
A. receiving soft values;
B. processing hard decision on the soft value to determine a codeword;
C. separating the codeword into a data part and a first parity part;
D. re-encoding the data part to get a second parity part;
E. checking if the first parity part and the second parity part are equivalent; and
F. if a result of step E is yes, stopping decoding the codeword; if the result of step E is no, processing a decoding algorithm on the codeword.

2. An early termination method with a re-encoding scheme for decoding of error correction codes, comprising the steps of:
A. receiving first soft values;
B. processing hard decision on the first soft values to determine a first codeword and processing a decoding algorithm on the first soft values to get second soft values;
C. separating the first codeword into a data part and a first parity part;
D. re-encoding the data part to get a second parity part;
E. processing hard decision on the second soft values to determine a second codeword and a third parity part of the second codeword;
F. checking if the second parity part and the third parity part are equivalent; and
G. if a result of step F is yes, stopping iterative decoding; if the result of step F is no, processing the decoding algorithm on the second codeword.

3. The early termination method according to claim 2, further comprising the steps of, after step G:
G1. after the decoding algorithm is processed, checking if a number of iterative calculation reaches a preset maximum number; and
G2. if a result of step H11 is yes, stopping iterative calculation of the decoding algorithm; if the result of step H11 is no, returning the processed codeword as the first soft values to repeat the procedure from step A.

4. An early termination method with a re-encoding scheme for decoding of error correction codes, comprising the steps of:
A. receiving soft values;
B. processing hard decision on the soft values to determine a first codeword;
C. separating the first codeword into a first data part and a first parity part;
D. re-encoding the first data part to get a second codeword;
E. separating the second codeword into a second data part and a second parity part;
F. calculating a number of mismatched bits between the first parity part and the second parity part;
G. checking if the number is greater than or equal to a preset value; and
H. if a result of step G is yes, processing a decoding algorithm on the first codeword; if the result of step G is no, processing the decoding algorithm on the second codeword.

5. The early termination method according to claim 4, further comprising the steps of, after step H:
H1. checking if a number of iterative calculation reaches a preset maximum number or a present termination condition of the decoding algorithm is met; and
H2. if a result of step G1 is yes, stopping iterative calculation of the decoding algorithm; if the result of step G1 is no, returning the processed codeword as the soft values to repeat the procedure from step A.
